(19) United States
(12) Patent Application Publication
(10) Pub. No.: US 2009/0007037 A1
(43) Pub. Date: Jan. 1, 2009

(54) Hybrid Fully-Silicided (FUSI)/Partially-Silicided (PASI) Structures

(75) Inventors: Louis Lu-Chen Hsu, Fishkill, NY (US); Jack Allan Mandelman, Flat Rock, NC (US); William Robert Tonti, Essex Junction, VT (US); Chih-Chao Yang, Glenmont, NY (US)

Correspondence Address: IBM CORPORATION, INTELLECTUAL PROPERTY LAW;DEPT 917, BLDG. 006-1, 3605 HIGHWAY 52 NORTH, ROCHESTER, MN, 55901-7829, US

(73) Assignee: INTERNATIONAL BUSINESS MACHINES CORPORATION, Armonk, NY (US)

(21) Appl. No.: 11/925,413

(22) Filed: Oct. 26, 2007

Related U.S. Application Data
(63) Continuation-in-part of application No. 11/770,798, filed on Jun. 29, 2007.

(51) Int. Cl. G06F 9/45

(52) U.S. Cl. 716/5

(57) ABSTRACT

Embodiments of the invention generally relate to methods, systems and design structures for semiconductor devices and more specifically to forming partially silicided and fully silicided structures. Fabricating the partially silicided and fully silicided structures may involve creating one or more gate stacks. A polysilicon layer of a first gate stack may be exposed and a first metal layer may be deposited thereon to create a partially silicided structure. Thereafter, a polysilicon layer of a second gate stack may be exposed and a second metal layer may be deposited thereon to form a fully silicided structure. In some embodiments, the polysilicon layers of one or more gate stacks may not be exposed, and resistors may be formed with the unsilicided polysilicon layers.

### CROSS-REFERENCE TO RELATED APPLICATIONS

This application is a continuation-in-part of co-pending U.S. patent application Ser. No. 11/770,798, filed Jun. 29, 2007, which is herein incorporated by reference.

### BACKGROUND OF THE INVENTION

1. Field of the Invention

The present invention is generally related to methods, systems and design structures for semiconductor devices and more specifically to forming partially silicided and fully silicided structures.

2. Description of the Related Art

Modern semiconductor devices are usually formed with one or more transistors, for example, a Metal Oxide Semiconductor Field Effect Transistor (MOSFET). Exemplary MOSFET based transistors include the n-channel (n-MOS), p-channel (p-MOS), and the Complementary Metal Oxide Semiconductor (CMOS) transistors. Conventionally, the gate structures of these MOSFETS are formed predominantly with a polysilicon material with an overlying silicide layer. Such gate structures are typically referred to as a Partially Silicided (PASI) gate structure because it comprises a silicide layer 131 formed adjacent to a polysilicon material.

One problem with using PASI gate structures is that a region depleted of majority carriers may be formed in the polysilicon material during operation of the transistor. For example, a depletion region may be formed when the gate conductor of an n-MOS is biased positively with respect to the source to invert channel region. The formation of such a depletion region may make a gate dielectric layer thicker than intended. In other words, the thickness of the dielectric layer would include the thickness of the depletion region.

As is understood in the art, variations in the thickness of the gate dielectric layer may seriously impair the performance of a transistor. For example, variations in thickness of the gate dielectric layer may affect the speed at which the transistor may be operated. Furthermore, variations in thickness of the gate dielectric layer may cause the threshold voltage to fluctuate, thereby affecting the reliability of the transistor.

To circumvent the problems of dielectric layer thickness variations in PASI gate structures, some transistors include Fully Silicided (FUSI) gate structures. FUSI gate structures comprise a silicide layer extending all the way to the gate dielectric layer. In other words, a polysilicon region is not included in the gate structure. However, there are several problems associated with using FUSI gate structures also. For instance, FUSI gate structures suffer from threshold voltage stability problems, particularly in circuits using narrow channel MOSFETs, such as Static Random Access Memories (SRAMs) and analog differential amplifiers. It is likely that the threshold voltage instability is caused due to incomplete silicide formation in small geometry structures, thereby creating regions of polysilicon at the interface of the gate dielectric material. As a result of the threshold voltage instability, devices must be modeled with a threshold voltage that is higher than desired for optimum performance. Therefore, FUSI gates are not desired in the formation of circuits using narrow channels devices.

Yet another problem with transistors using FUSI gates is that over-voltages may not be applied on a FUSI gate structure. For example, Input/Output (IO) devices may frequently be operated at voltages that are far in excess of the on chip power supply voltages. Such voltages may present severe gate dielectric reliability concerns for FUSI gated IO devices. For example, a chip operating with a 1.2 Volt internal voltage supply may have to interface with external circuits driving input gates on the chip to 3.3 Volts or higher. It is likely that the high voltages applied at the gate may result in dielectric breakdown at the dielectric layer, thereby affecting performance of the device.

To avoid dielectric breakdown in FUSI gates, it may be necessary to thicken the dielectric layer which may significantly increase fabrication cost and complexity. Therefore, in circuits involving IO devices, the use of PASI transistors may be more desirable because a polysilicon gate, by its inherent gate depletion provides reliable operation with an overvoltage. In other words, a gate depletion region formed in PASI gates may provide a buffer region that drops a portion of the high input voltage, thereby reducing the possibility of dielectric breakdown.

A given circuit may include several devices, some of which may perform better with PASI structures, while others may perform better with FUSI structures. But forming PASI structures and FUSI structures separately may greatly increase the cost and complexity of fabrication.

Accordingly, there is a need for a semiconductor structure comprising both PASI structures and FUSI structures, and methods for efficiently fabricating both PASI structures and FUSI structures on the same substrate.

### SUMMARY OF THE INVENTION

The present invention is generally related to semiconductor devices and more specifically to forming partially silicided and fully silicided structures.

One embodiment of the invention provides a method for forming a semiconductor structure. The method steps, in sequence, generally comprise forming a plurality of stack structures on a common substrate comprising at least one first stack structure and at least one second stack structure, each of the first stack structures and the second stack structures comprising a polysilicon layer and an oxide layer disposed on the polysilicon layer, whereby the at least one first stack structure is manufactured as a fully silicided (FUSI) stack and the at least one second stack structure is manufactured as a partially silicided (PASI) stack.

The method further comprises exposing the polysilicon layer of the at least one second stack structure and depositing a first metal layer on the polysilicon layer of the at least one second stack structure and forming a first silicide layer on the polysilicon layer of the at least one second stack structure. The method still further comprises exposing the polysilicon layer of the at least one first stack structure and depositing a second metal layer on the polysilicon layer of the at least one first stack structure; and then forming a second silicide layer in the at least one first stack structure by causing the second metal layer to react with the polysilicon layer of the at least one first stack structure, wherein the second metal layer fully converts the polysilicon layer of the at least one first stack structure into the second silicide layer.

Another embodiment of the invention provides a semiconductor structure, generally comprising at least one fully silicided (FUSI) region, at least one partially silicided (PASI) region, and at least one resistor on a common substrate. The resistor comprises an unsilicided polysilicon region, and a first fully silicided region formed adjacent to a first surface of the unsilicided polysilicon region and a second fully silicided region formed adjacent to a second surface of the unsilicided polysilicon region, wherein each of the first fully silicided region and the second fully silicided region connects the resistor to a respective device.

Yet another embodiment of the invention provides a semiconductor structure comprising at least one resistor comprising an unsilicided polysilicon region and a first fully silicided region being formed adjacent to a first surface of the unsilicided polysilicon region and a second fully silicided region being formed adjacent to a second surface of the unsilicided polysilicon region, wherein each of the first fully silicided region and the second fully silicided region connects the resistor to a respective device.

Yet another embodiment of the invention provides a design structure embodied in a machine readable medium for at least one of designing, manufacturing, and testing a design. The design structure generally includes a semiconductor structure having at least one resistor comprising an unsilicided polysilicon region and a first fully silicided region being formed adjacent to a first surface of the unsilicided polysilicon region and a second fully silicided region being formed adjacent to a second surface of the unsilicided polysilicon region, wherein each of the first fully silicided region and the second fully silicided region connects the resistor to a respective device.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 illustrates a Partially Silicided (PASI) gate transistor according to the prior art.

FIG. 2 illustrates a Fully Silicided (FUSI) gate transistor according to the prior art.

FIG. 3 illustrates an exemplary system according to an embodiment of the invention.

FIG. 4 illustrates exemplary gate stacks according to an embodiment of the invention.

FIG. 5 illustrates patterning of a photoresist mask on the gate stacks of FIG. 4 according to an embodiment of the invention.

FIG. 6 illustrates etching of an oxide layer from a gate stack according to an embodiment of the invention.

FIG. 7 illustrates deposition of a first metal layer on the gate stacks according to an embodiment of the invention.

FIG. 8 illustrates selective deposition of the first metal layer according to an embodiment of the invention.

FIG. 9 illustrates the results of a first set of one or more annealing procedures according to an embodiment of the invention.

FIG. 10 illustrates deposition of a second metal layer on the gate stacks according to an embodiment of the invention.

FIG. 11 illustrates the results of a second set of annealing procedures according to an embodiment of the invention.

FIG. 12 is a flow diagram of a design process used in semiconductor design, manufacturing, and/or test.

### DETAILED DESCRIPTION OF THE PREFERRED EMBODIMENTS

The present invention is generally related to semiconductor devices and more specifically to forming partially silicided and fully silicided structures. Fabricating the partially silicided and fully silicided structures may involve creating one or more gate stacks. A polysilicon layer of a first gate stack may be exposed and a first metal layer may be deposited thereon to create a partially silicided structure. Thereafter, a polysilicon layer of a second gate stack may be exposed and a second metal layer may be deposited thereon to form a fully silicided structure. In some embodiments, the polysilicon layers of one or more gate stacks may not be exposed, and resistors may be formed with the unsilicided polysilicon layers.

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

### Exemplary System

FIG. 1 illustrates an exemplary MOSFET structure 100 according to an embodiment of the invention. As illustrated in FIG. 1, MOSFET structure 100 may include a source region 110, a drain region 120, and a gate structure 130 formed on a substrate 140. Gate structure 130 may comprise a silicide layer 131 formed on a doped polysilicon layer 132. Gate structure 130 may be insulated using nitride capping layers 133 as illustrated in FIG. 1. Furthermore, a gate dielectric layer 143 may be formed between the polysilicon layer 132 and the substrate 140 comprising the source region 110 and drain region 120, as illustrated. The gate structure 130 illustrated in FIG. 1 is hereinafter referred to as a Partially Silicided (PASI) gate structure because it comprises a silicide layer 131 formed therein.

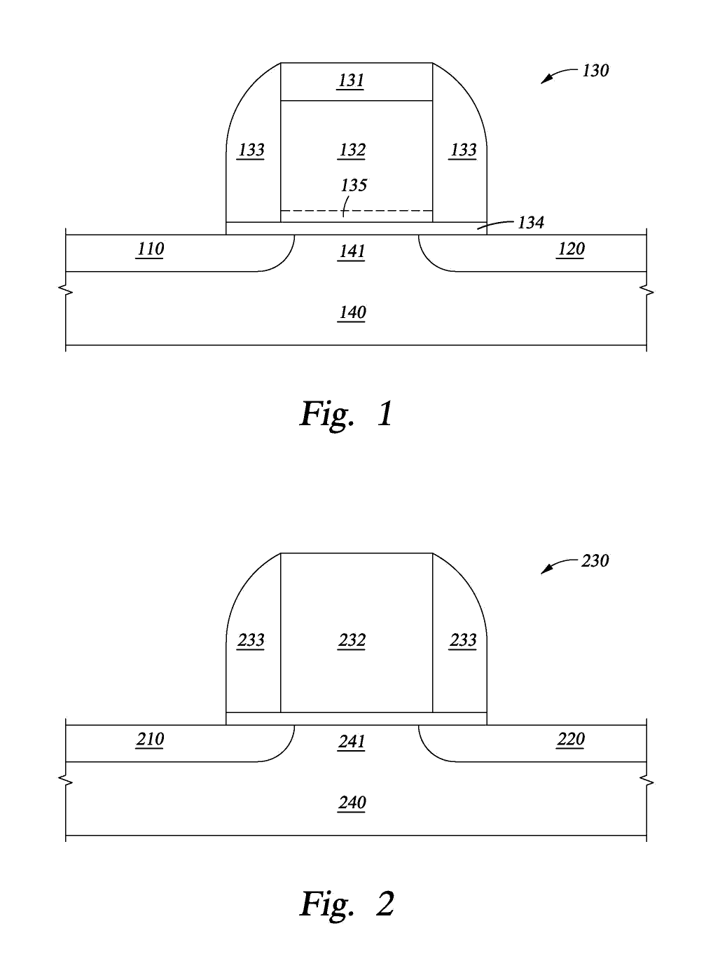

FIG. 2 illustrates an exemplary MOSFET structure 200 using a FUSI gate structure, according to an embodiment of the invention. MOSFET 200 may be similar to the MOSFET 100 illustrated in FIG. 1 and may include a source region 210, drain region 220, and a gate structure 230 formed on a substrate 240. Gate structure 230 may be a FUSI gate structure. Accordingly, gate structure 230 may be formed with a suicide layer 232 extending all the way to the gate dielectric layer 234. By avoiding the polysilicon layer, FUSI gate structures, for example FUSI gate structure 230, avoid the problems with variations in gate dielectric thicknesses that afflict PASI gates.

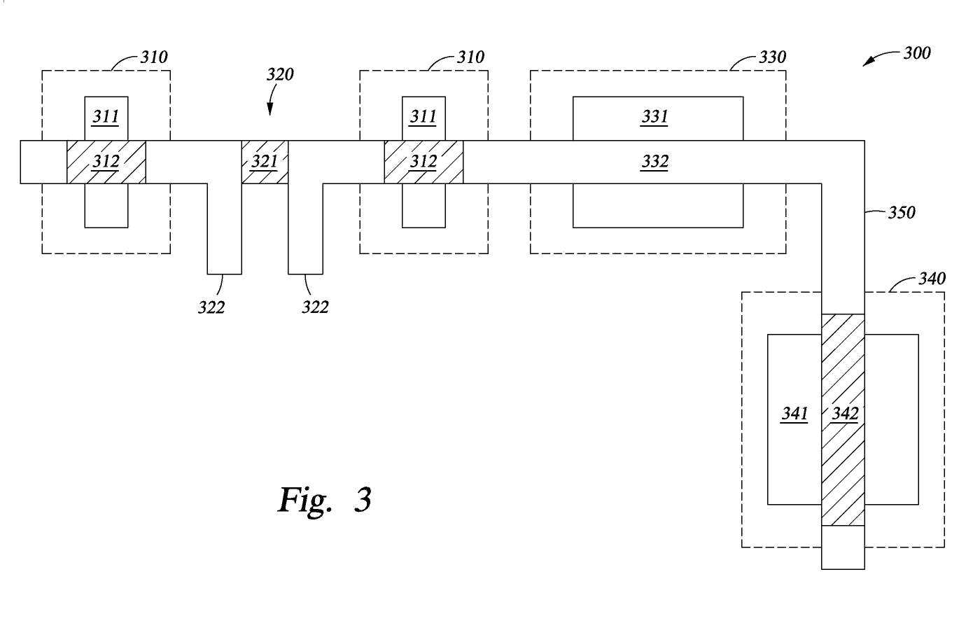

FIG. 3 illustrates a top view of an exemplary system 300 including PASI gate and FUSI gate devices according to an embodiment of the invention. Specifically illustrated in FIG. 3 are two PASI gate devices 310, a resistor 320, a FUSI gate device 330, and a PASI gate IO device 340. The particular devices and the device configuration depicted in FIG. 3 are shown for illustrative purposes only. More generally any number, type, combination and configuration of PASI gate and FUSI gate devices fall within the purview of the invention.

In one embodiment of the invention PASI gate devices 310 may be narrow channel devices. For example, in a particular embodiment, the PASI gate devices 310 may be one of an SRAM cell or a differential amplifier. Accordingly, the active regions 311 of the PASI gate devices 310 are shown having a relatively smaller geometry. Active regions 311 may be active silicon conductor regions of a transistor that are isolated by shallow trench isolation. For example, an active region 311 may include a source region, a drain region, and a channel region of a transistor.

As illustrated in FIG. 3, the active regions 311 may include a gate structure 332 formed thereon. Gate structures 312 may be PASI gate structures. As discussed above, it may be more desirable to form narrow channel devices using PASI gates rather than FUSI gates. FUSI gates may not be used in narrow channel devices because of the high likelihood of threshold voltage instability. The threshold voltage instability may be caused due to incomplete silicide formation in small geometry structures, thereby creating micro regions of polysilicon at the interface of the gate dielectric material. Exemplary narrow channel devices include SRAMs and differential amplifiers. Because threshold voltages are more stable and controllable in PASI gates, PASI gate transistors may be used to form narrow channel devices.

In some embodiments, it may be necessary to include one or more resistors in a circuit. For example, in system 300, a resistor 320 connects the gates of PASI gate transistors 310. The use of resistors may be particularly necessary in analog circuits. Embodiments of the invention also provide precision polysilicon resistors that may be formed during fabrication. The precision polysilocon resistor 320 may be superior to prior art resistors. For example, prior art resistors form a resistive element within a portion of a polysilicon line from which silicidation was blocked, and connect to the resistive element via adjacent partially silicided polysilicon conductors. The presence of adjacent partially silicided regions may introduce a variable component to the total resistance.

However, precision resistor 320 includes a polysilicon structure 321 connected to one or more other devices (for example, PASI gate transistors 310 in FIG. 3) using FUSI sections 322. By using the FUSI sections 322, adjacent to the unsilicided polysilicon structure 321 much of the variable resistance component may be avoided, thereby making the resistor more precise. This may be because the relatively low sheet resistance of FUSI sections 322 in comparison to the unsilicided polysilicon structure 321 makes the contribution to the total resistance by the FUSI sections 322 negligible.

System 300 may also include FUSI gate device 330. As illustrated in FIG. 3, a FUSI gate 332 may be formed on the active region 331 of the FUSI gate device 330. The active region 331 may be larger than the active region 311, as illustrated in FIG. 3. FUSI fate device 330 may be a high performance device where variations in gate dielectric thickness are not desired in order to allow operation of the device at high speeds.

System 300 also includes a PASI gate IO device 340. As illustrated PASI IO device 340 may include a PASI gate structure 342 formed over an active region 341. PASI gate IO device may interface with an IO device operating at a greater voltage than the devices in system 300. Therefore, a depletion region formed in the PASI gate structure 342 may diminish the effect of overvoltages that may result in breakdown in the gate dielectric layer.

As illustrated in FIG. 3, FUSI gate device 330 and PASI gate IO device 340 may be connected using a FUSI interconnect 350. In one embodiment, FUSI interconnect 350 may be a fin structure formed over a shallow trench isolation region to interconnect the FUSI gate device 330 and the PASI gate IO device 340. While the FUSI interconnect 350 is shown connecting the FUSI gate device 330 and the PASI gate IO device 340, one skilled in the art will recognize that the FUSI interconnect 350 may be used to connect any device in system 300.

### Method for Fabricating PASI and FUSI Structures

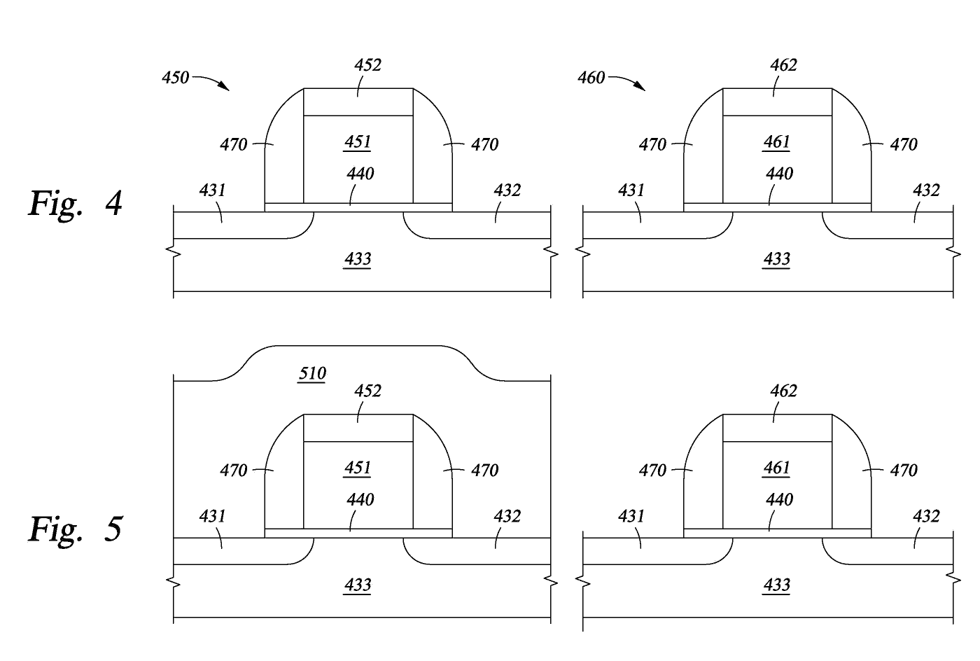

Fabrication of PASI and FUSI gate structures may begin by first forming gate stacks using one or more prior art methods. FIG. 4 illustrates two exemplary transistor structures 410 and 420 that may be formed using prior art techniques. Transistors 410 and 420 may be formed on the same substrate and may be a part of the same circuit. In one embodiment, transistor 410 may be used to form a FUSI gate transistor and transistor 420 may be used to form a PASI gate transistor.

As illustrated in FIG. 4, each of the transistors 410 and 420 may include a source region 431 and a drain region 432 formed on a substrate 433. Substrate 433 may be formed with any suitable semiconductor material including, but not limited to, Silicon, Germanium, Silicon Germanium, Gallium Arsenic, Indium Phosphorus, and the like. In one embodiment substrate 433 may be a bulk silicon substrate. Alternatively, a silicon on insulator (SOI) substrate may also be used

Source regions 431 and 432 may be doped with a predetermined amount of a suitable p-type or n-type dopant. Any suitable method for doping such as a diffusion-based procedure and/or an ion implantation based procedure may be used to incorporate dopants into the substrate 433 to form the source regions 431 and drain regions 432.

A gate dielectric layer 440 may be formed on the substrate 433 using any conventional thermal growing process or by deposition. The gate dielectric layer may be composed of an oxide material including, but not limited to, SiO₂, Al₂O₃, ZrO₂, HfO₂, Ta₂O₃, TiO₂, silicates, or any combination of the above materials, with or without the addition of nitrogen. The gate dielectric layer is typically a relatively thin layer. For example, in some embodiments, the gate dielectric layer 440 is between 1 and 10 nanometers.

A gate stack may be formed on the dielectric layer 440, as illustrated in FIG. 4. For example, transistor 410 comprises a gate stack 450 and transistor 420 comprises a gate stack 460 in FIG. 4. Each gate stack may include a polysilicon layer and an oxide layer formed thereon. For example, gate stack 450 comprises a polysilicon layer 451 and an oxide layer 452 formed on the polysilicon layer 452. Similarly, gate stack 460 comprises a polysilicon layer 461 and a oxide layer 462 formed on the polysilicon layer 461 The polysilicon and oxide layers may be insulated using nitride spacers 470, as illustrated in FIG. 4. Each of gate stacks 450 and 460 may be formed using conventional techniques such as deposition of semiconductor and nitride layers, patterning a mask on a layer of deposited material, etching, and the like to form the gate stacks.

In one embodiment of the invention, forming the FUSI and PASI gate structure may begin by depositing and patterning a layer of photoresist on the transistors 410 and 420. Patterning the photoresist layers may involve exposing the gate stacks that may be used to form PASI gate structures. For example, FIG. 5 illustrates a photoresist layer 510 formed on the gate stack 450, whereas gate stack 460 is exposed by patterning of the photoresist layer 510. Exposing the gate stack 460 may expose the oxide layer 462 of the gate stack 460 for subsequent fabrication processes.

The oxide layer 462 exposed by the patterning of the photoresist mask 510 may be removed using a suitable etching process. For example, in one embodiment, a wet etching process using an etchant such as hydrofluoric acid (HF) may be used to remove the oxide layer exposed by the photoresist mask 510. However, any alternative etchant, or alternative etching process, for example, a dry etching process may also be used to remove the oxide layer 462.

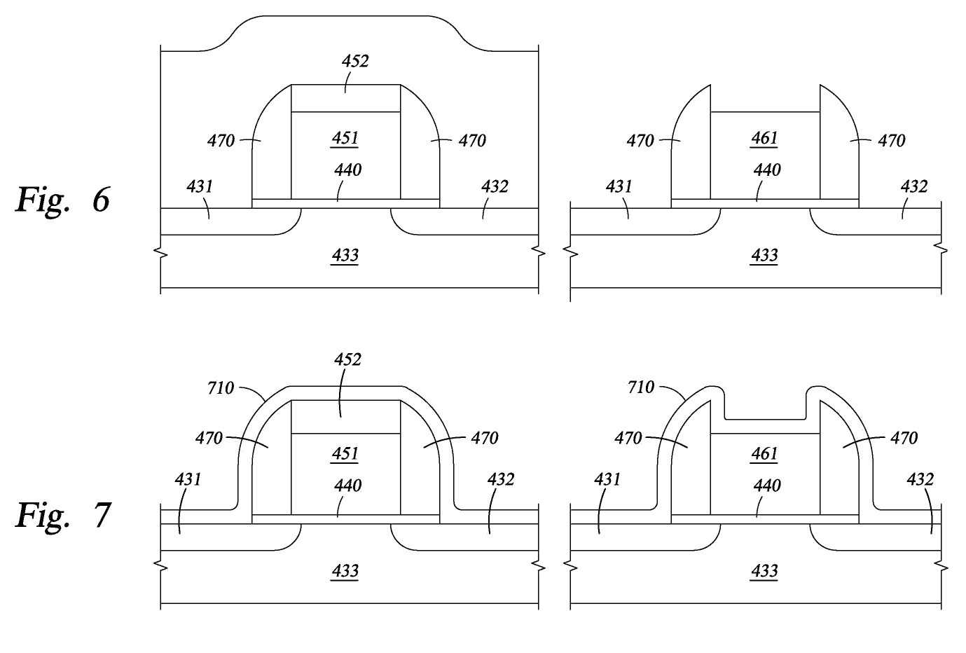

FIG. 6 illustrates exemplary the gate stacks 450 and 460 removal of the oxide layer 462, according to an embodiment of the invention. As illustrated in FIG. 6, the oxide layer 451 of the gate stack 450 is protected by the photoresist mask 510 during etching, and is therefore preserved. On the other hand, the oxide layer 462 of gate stack 460 is removed by the etchant, thereby exposing the polysilicon layer 461 of gate stack 460.

After the oxide layer 462 is removed, the photoresist layer 510 may be stripped and exposed surfaces may be cleaned using dilute HF to remove any particles left behind after the etching process. A layer of an electropositive material, for example, for example, a suitable metal may be deposited on the surface of the exposed surfaces. In one embodiment of the invention, a layer of cobalt may be deposited on the exposed surfaces. FIG. 7 illustrates a metal layer 710 deposited on the exposed surfaces of the transistors 410 and 420. The metal layer 710 may be deposited using a sputtering process, or, alternatively, by low temperature Chemical Vapor Deposition (CVD) or Physical Vapor Deposition (PVD). In one embodiment, chemical vapor deposition may be performed at 450° C. The thickness of the metal layer 710 may be between around 5 nanometers and around 30 nanometers.

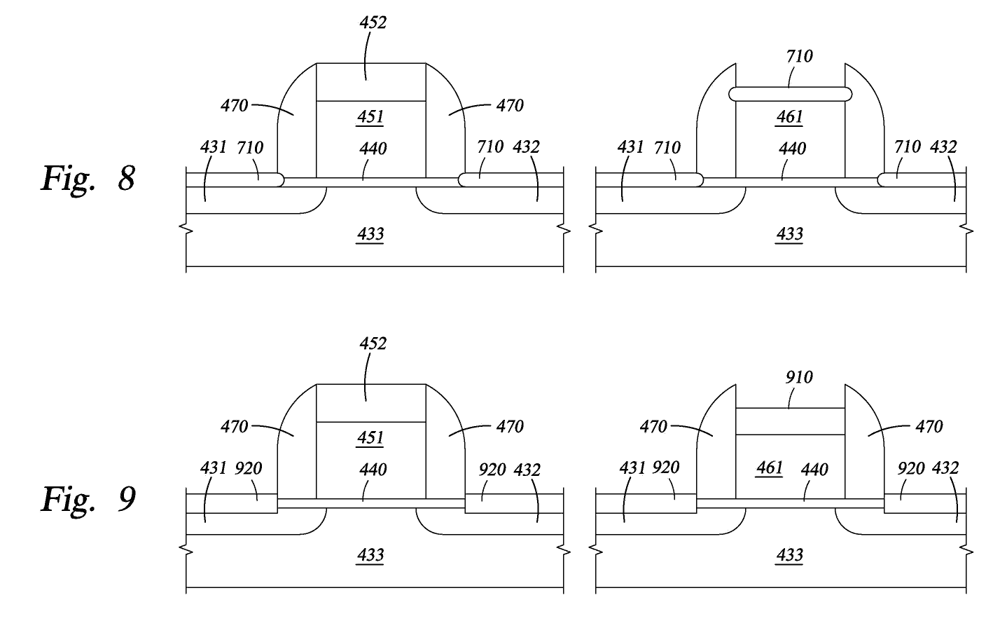

Alternatively, the metal layer 710 may be formed selectively on exposed silicon surfaces. For example, FIG. 8 illustrates the metal layer 710 formed on the polysilicon layer 461 and the source and drain regions of each of transistors 410 and 420. If a selective metal layer, as illustrated in FIG. 8 is formed, subsequent process steps for removing the cobalt layers formed on the oxide layer 451 of transistor 410 and the nitride spacers 470 of transistors 410 and 420 may be avoided. Selective formation of the metal layer 710 may involve electroplating, either with or without electrodes being present in an electroplating apparatus. The plating may be conducted in a plating bath comprising a solution of a metal salt, for example, a cobalt salt, at or near room temperature. The metal may deposit selectively on surfaces of conductive materials such as, for example, polysilicon layer 461 and crystalline silicon of the source and drain regions of transistors 410 and 420. However, the metal may not deposit on insulator surfaces such as the nitride spacers 470 and the oxide layer 451 of transistor 410.

The deposited metal layer 710 may be made to react with the polysilicon layer 462 and the source and drain regions of transistors 410 and 420 in one or more annealing procedures. For example, in one embodiment, a first annealing procedure may be performed between around 450° C. and 550° C. In one embodiment of the invention, the first annealing procedure may be a rapid thermal anneal (RTA). The first anneal procedure may begin a silicidation process for forming a PASI gate structure at transistor 420. For example, the first anneal procedure may cause the metal layer 710 to react with the polysilicon layer 462 of transistor 420, thereby forming a silicide layer 910, as illustrated in FIG. 9. As depicted in FIG. 9, the silicide layer 910 is formed on top of the polysilicon layer 462 of transistor 420, thereby forming a PASI gate transistor.

In one embodiment, if the metal layer 710 was not selectively deposited on the silicon surfaces, unreacted metal on the oxide layer 451 and the nitride spacers 470 may be removed using a selective wet etch comprising, for example, hydrochloric acid (HCl). In one embodiment, the HCl may comprise around 30% hydrogen peroxide (H₂O₂). In one embodiment of the invention, following removal of the excess cobalt using the wet chemical etch, a second anneal procedure may be performed. The second anneal procedure may result in increasing the volume of the silicide layer 910 to a desired depth. In one embodiment, the depth of the silicide layer after the second anneal procedure may be between around 5 nanometers and 15 nanometers. Furthermore, the second anneal procedure may result in the formation of silicide layers 920 on the source and drain regions of each of transistors 410 and 420, as illustrated in FIG. 9. In a particular embodiment, the second anneal procedure may be performed for around 30 seconds at around 700° C.

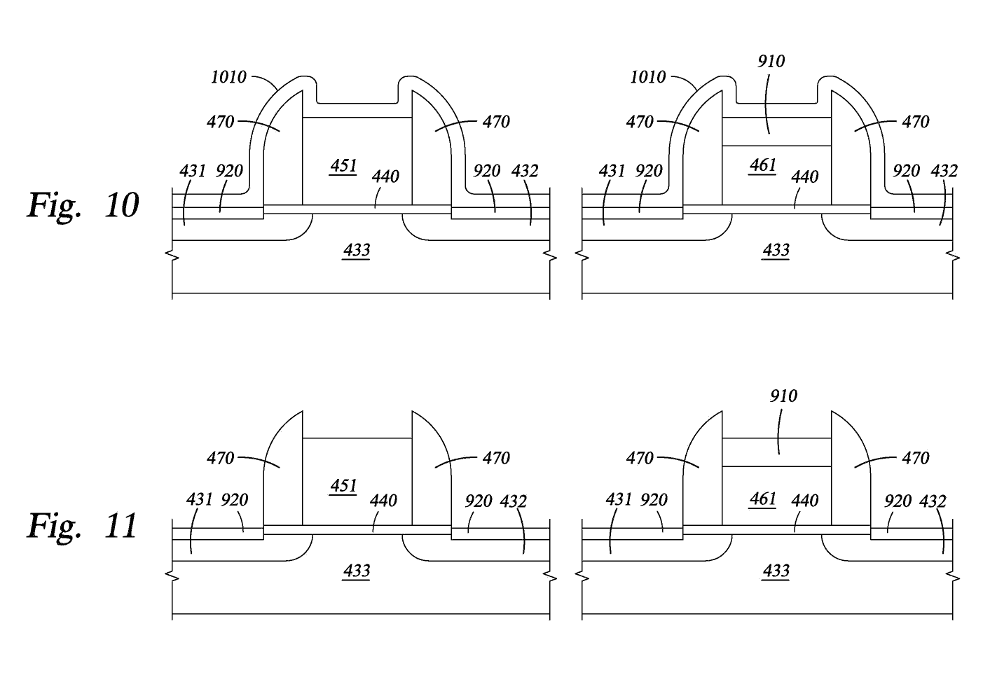

Subsequent to the formation of the PASI gate structure at transistor 420, oxide cap 451 of transistor 410 may be removed. In one embodiment, oxide cap 451 may be removed using a suitable etchant, for example, buffered HF. Following removal of the oxide layer 451, exposed surfaces may be cleaned by an argon sputtering cleaning procedure. A second metal layer 1010 may then be deposited on the exposed surfaces using a Physical Vapor Deposition (PVD) process, as illustrated in FIG. 10. The second metal layer 1010 may comprise a metal different from the metal used in the metal layer 710. For example, in one embodiment, the metal layer 710 may comprise cobalt, whereas the metal layer 1010 may comprise nickel. In a particular embodiment, the metal layer 1010 may be between around 20 nanometers and 120 nanometers thick. In some embodiments, in addition to the metal layer 1010, a Titanium Nitride (TiN) layer may be deposited on the metal layer 1010. The TiN layer may be around 10 nanometers thick and may be configured to block surface diffusion and improve gate work function control.

A low temperature anneal procedure may be performed to diffuse the metal layer 1010 into the polysilicon layer 452 to form a silicide material. In one embodiment, the anneal procedure may comprise a rapid thermal anneal (RTA) ramped procedure at around 10° C./second, followed by a soak period and a ramp down period. The soak period may last up to around 90 seconds at a temperature between around 350° C. to around 550° C. In some embodiments, a spike anneal procedure may be performed. In other words, the soak anneal may be avoided.

The silicide layers 910 and 920 may substantially block the diffusion of the metal layer 1010 into the source and drain regions of transistors 410 and 420 and the polysilicon layer 461 of transistor 420, thereby preventing formation of nickel silicide in these areas. The metal layer 1010, however, may diffuse completely into the polysilicon layer 451 of transistor 410, thereby creating a FUSI gate structure.

Following formation of the FUSI gate structure at transistor 410, the optional TiN layer and any excess metal may be removed using a wet etching process. The wet etching process may involve the use of any combination of sulfuric acid, hydrogen peroxide, and water as the etchant. The resulting transistor structures are illustrated in FIG. 11. As illustrated in FIG. 11, a FUSI gate transistor 410 and a PASI gate transistor 420 may be formed as a result of the method described above.

While fabrication of two transistors 410 and 420 are described herein, one skilled in the art will recognize that any number of FUSI gate and PASI gate transistors may be constructed simultaneously while performing the method steps described above. By providing a simple method for simultaneously fabricating PASI and FUSI gate devices, embodiments of the invention greatly reduce the cost and complexity of fabrication.

In one embodiment of the invention, fabricating a resistor 320 may involve preventing silicidation of at least a part of one or more polysilicon lines. For example, referring to FIG. 4 any one of the oxide caps 452 and 462 may not be removed to prevent silicidation or at least a portion of the respective polysilicon lines 451 and 461. By selectively blocking silicidation from portions of a polysilicon line, and connecting those unsilicided portions with adjacent FUSI conductors, for example, FUSI sections 322 in FIG. 3, high precision resistors may be realized. The resistors may be high precision resistors because the contribution of the FUSI conductors to the overall resistance is negligible. Therefore, the resistance can be precisely computed based on the geometry, for example, length, width, height, and the like, of the unsilicided polysilicon line.

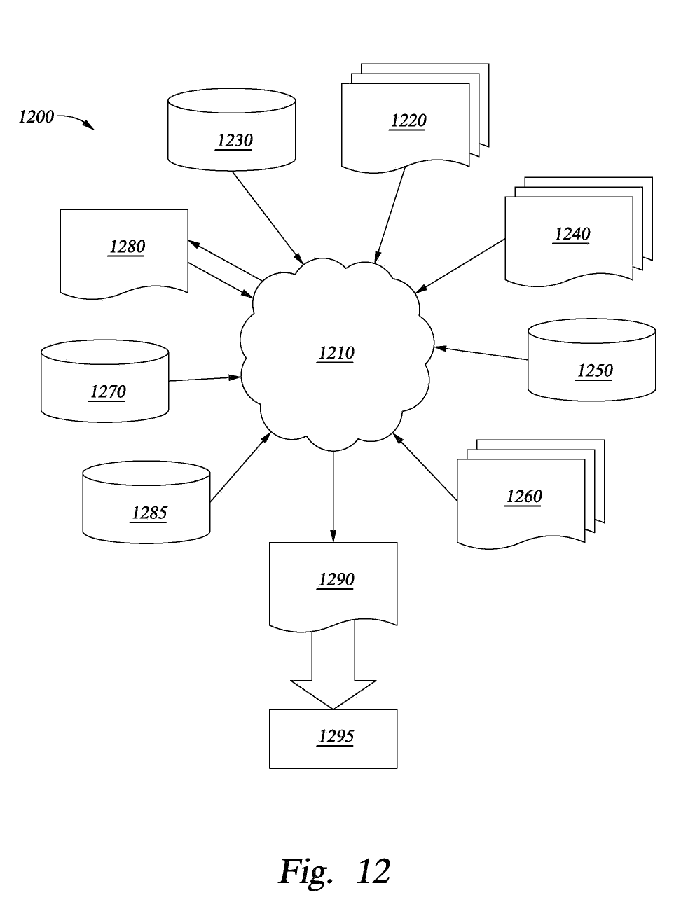

FIG. 12 shows a block diagram of an example design flow 1200. Design flow 1200 may vary depending on the type of IC being designed. For example, a design flow 1200 for building an application specific IC (ASIC) may differ from a design flow 1200 for designing a standard component. Design structure 1220 is preferably an input to a design process 1210 and may come from an IP provider, a core developer, or other design company or may be generated by the operator of the design flow, or from other sources. Design structure 1220 comprises the circuits described above and shown in FIGS. 3-11 in the form of schematics or HDL, a hardware-description language (e.g., Verilog, VHDL, C, etc.). Design structure 1220 may be contained on one or more machine readable medium. For example, design structure 1220 may be a text file or a graphical representation of circuit 1200. Design process 1210 preferably synthesizes (or translates) the circuits described above in and shown in FIGS. 3-11 into a netlist 1280, where netlist 1280 is, for example, a list of wires, transistors, logic gates, control circuits, I/O, models, etc. that describes the connections to other elements and circuits in an integrated circuit design and recorded on at least one of machine readable medium. This may be an iterative process in which netlist 1280 is resynthesized one or more times depending on design specifications and parameters for the circuit.

Design process 1210 may include using a variety of inputs; for example, inputs from library elements 1230 which may house a set of commonly used elements, circuits, and devices, including models, layouts, and symbolic representations, for a given manufacturing technology (e.g., different technology nodes, 32 nm, 45 nm, 90 nm, etc.), design specifications 1240, characterization data 1250, verification data 1260, design rules 1270, and test data files 1285 (which may include test patterns and other testing information). Design process 1210 may further include, for example, standard circuit design processes such as timing analysis, verification, design rule checking, place and route operations, etc. One of ordinary skill in the art of integrated circuit design can appreciate the extent of possible electronic design automation tools and applications used in design process 1210 without deviating from the scope and spirit of the invention. The design structure of the invention is not limited to any specific design flow.

Design process 1210 preferably translates an embodiment of the invention as described above and shown in FIGS. 3-11, for example, along with any additional integrated circuit design or data (if applicable), into a second design structure 1290. Design structure 1290 resides on a storage medium in a data format used for the exchange of layout data of integrated circuits (e.g., information stored in a GDSII (GDS2), GL1, OASIS, or any other suitable format for storing such design structures). Design structure 1290 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as described above and shown in FIGS. 3-11, for example. Design structure 1290 may then proceed to a stage 1295 where, for example, design structure 1290: proceeds to tape-out, is released to manufacturing, is released to a mask house, is sent to another design house, is sent back to the customer, etc.

### Conclusion

By allowing formation of FUSI and PASI structures on the same substrate using method steps disclosed herein, embodiments of the invention may reduce the cost and complexity of fabrication of circuits requiring both PASI and FUSI structures. Furthermore, embodiments of the invention also facilitate formation of high precision resistors that may be superior to prior art resistors.

While the foregoing is directed to embodiments of the present invention, other and further embodiments of the invention may be devised without departing from the basic scope thereof, and the scope thereof is determined by the claims that follow.

What is claimed is:

1. A design structure embodied in a machine readable storage medium for at least one of designing, manufacturing, and testing a design, the design structure comprising:
a semiconductor structure, comprising, on a common substrate:
at least one fully silicided (FUSI) region;
at least one partially silicided (PASI) region; and
at least one resistor comprising an unsilicided polysilicon region, a first fully silicided region formed adjacent to a first surface of the unsilicided polysilicon region and a second fully silicided region formed adjacent to a second surface of the unsilicided polysilicon region, wherein each of the first fully silicided region and the second fully silicided region connects the resistor to a respective device.

2. The design structure of claim 1, wherein the design structure comprises a netlist, which describes the semiconductor structure.

3. The design structure of claim 1, wherein the design structure resides on the storage medium as a data format used for the exchange of layout data of integrated circuits.

4. The design structure of claim 1, wherein the design structure includes at least one of test data files, characterization data, verification data, or design specifications.
